(19) United States
(12) Patent Application Publication
(10) Pub. No.: US 2009/0101981 A1
(43) Pub. Date: Apr. 23, 2009

(54) ONE-TRANSISTOR TYPE DRAM

(76) Inventor: Heon Yong CHANG, Suwon-si (KR)

Correspondence Address: LADAS & PARRY LLP, 224 SOUTH MICHIGAN AVENUE, SUITE 1600, CHICAGO, IL, 60604, US

(21) Appl. No.: 12/164,153

(22) Filed: Jun. 30, 2008

(30) Foreign Application Priority Data
Oct. 17, 2007 (KR) 10-2007-0104561

(51) Int. Cl. H01L 27/108; H01L 21/8242

(52) U.S. Cl. 257/368; 438/294; 257/E27.084; 257/E21.646

(57) ABSTRACT

A one-transistor type DRAM simplifies a manufacturing process and reduces the height of a chip. In the one-transistor type DRAM, an active region is defined by a device isolating film. A first word line and a second word line extend across the active region and the device isolating film. A common source region is formed in the portion of the active region between the first and second word lines. Drain regions are formed in the portions of the active region outside of the first and second word lines. A first metal line and a second metal line are connected to the common source region and the drain region, respectively, and a bit line is connected to the second metal line.

### CROSS-REFERENCE TO RELATED APPLICATION

The present application claims priority to Korean patent application number 10-2007-0104561 filed on Oct. 17, 2007, which is incorporated by reference in its entirety.

### BACKGROUND OF THE INVENTION

The present invention relates generally to a one-transistor type DRAM, and more particularly to a one-transistor type DRAM including two transistors sharing a source, and a bit line crossing an upper portion of the active region to reduce the cell size.

A DRAM is a semiconductor memory device comprising a plurality of unit cells, and each cell of a typical DRAM device includes a transistor and a capacitor.

The capacitor stores digital data having a logic 1 (high) or a logic 0 (low). In order to maintain the voltage level corresponding to the data stored in the capacitor, the DRAM performs a refresh operation (a data re-charging operation), after a given time interval. One example of a DRAM device having unit cells which is currently being developed is a synchronized semiconductor memory device referred to as double data rate synchronized dynamic random access memory (DDR) SDRAM.

As the capacity of a DRAM devices approaches the gigabyte range, the chip size is typically required to be larger. The increases chip size serves as a burden, since a small chip size can be considered advantageous to a system.

Specifically, the height of a lower electrode in the capacitor of the unit cell is required to be greater than 2 μm in order to increase the capacitance of the capacitor, and the capacitor implements a dielectric material having a high dielectric constant. As a consequence, patterning of the capacitor has become difficult, and leakage current has increased.

In conventional unit cell structures, the bit line is positioned to cross an upper portion of the device isolating film rather than the upper portion of the active region, and the convention DRAM device having this configuration cannot have a cell size below 6F2.

### BRIEF SUMMARY OF THE INVENTION

The present invention includes a one-transistor type DRAM that simplifies a manufacturing process without capacitor related processes and reduces the height of a chip.

The present invention includes a one-transistor type DRAM including two transistors that share a source, and a bit line that crosses an upper portion of an active region to reduce the cell size.

In an embodiment of the present invention an island-type metal line is formed over a drain region, and a contact plug is connected to the island-type metal line so as to connect a bit line to a drain. When using this configuration, it is possible to lower the height of the contact plug and prevent surface damage of the drain.

According to an embodiment of the present invention, a one-transistor type DRAM comprises: first and second word lines that cross an active region and a device isolating film; a common source region in the active region disposed between the first and second word lines; a drain region formed in the active region disposed outside the first and second word lines; first and second metal lines connected to the common source region and the drain region, respectively; and a bit line connected to the second metal line.

### BRIEF DESCRIPTION OF THE DRAWINGS

FIGS. 1a to 1f are diagrams showing the layout of a one-transistor type DRAM according to an embodiment of the present invention.

FIGS. 2a to 2e are diagrams showing the layout of a one-transistor type DRAM according to another embodiment of the present invention.

FIGS. 3a to 3e are diagrams showing the layout of a one-transistor type DRAM according to another embodiment of the present invention.

### DESCRIPTION OF EMBODIMENTS

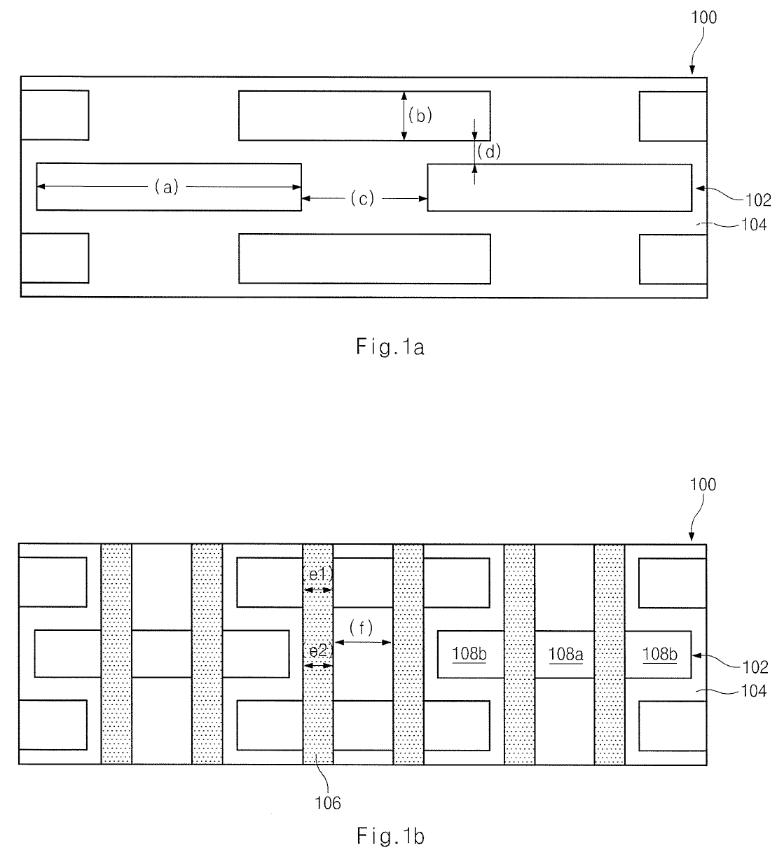

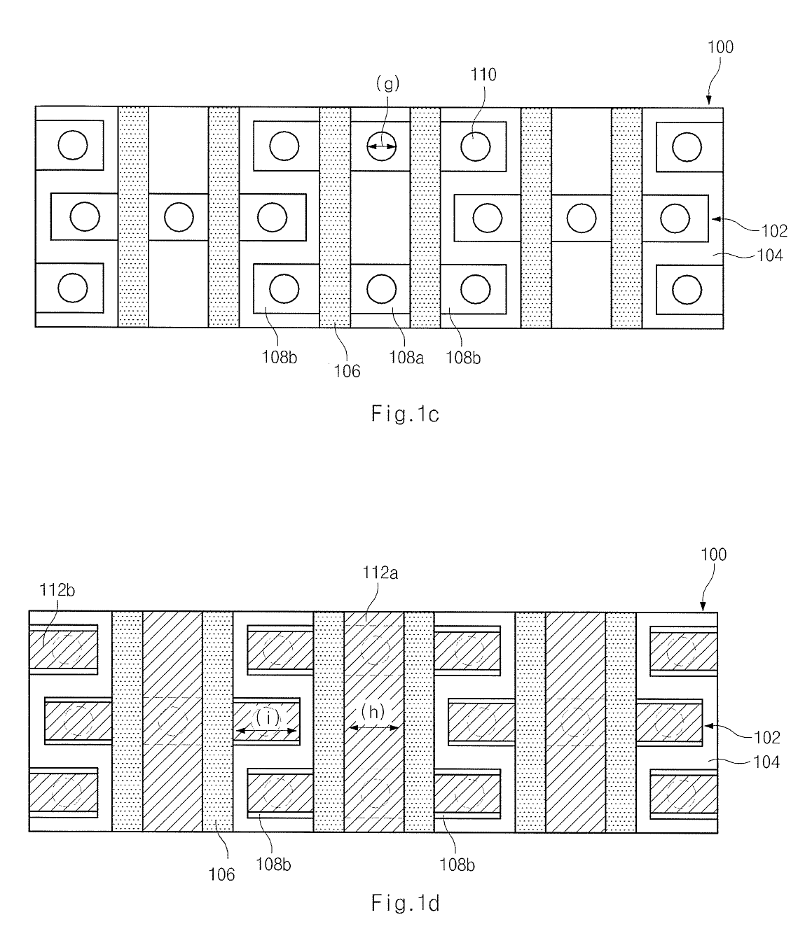

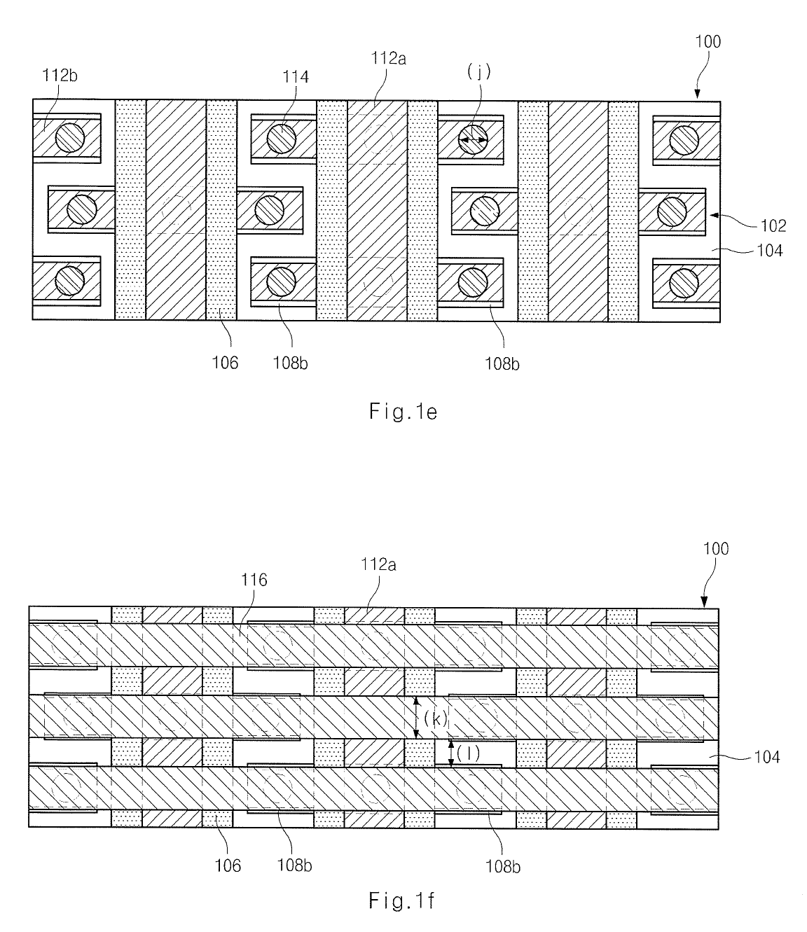

FIGS. 1a to 1f are diagrams showing the layout of a one-transistor type DRAM according to an embodiment of the present invention.

Referring to FIG. 1a, a device isolating film 104 that defines active regions 102 is formed on a semiconductor substrate 100. The active regions 102 are formed as one of an I-type, a T-type, and a Z-type. In the active region, the width of the middle portion can be identical to or different from the width of the edge in a major axis direction (the direction extending along the length (a)) of the active region 102.

The length (a) of the active region (which extends in the major axis direction) extends in the same direction (i.e., is parallel to) the bit line formed in a subsequent process, and the length (a) of the active region is formed to be longer than the length (b) of the active region extending in the minor axis direction. The length (b) of the active region 102 extends in the same direction (i.e., is parallel to) the word line formed during a subsequent process.

A length (c) of the space between active regions 102 in the major axis direction is formed to be different from length (d) of the space between the active regions 102 in the minor axis direction. The length (c) is preferably longer than the length (d).

In the active region 102, the length (a) of the active region extending in the major axis direction is formed to be different from the length (c) of the space between the active regions 102. The length (a) is preferably formed to be longer than the length (c).

In a subsequent process, two word lines, two drain regions, and one source region are going to be formed along the length (a) of the active region extending in the major axis direction. As such, the length (c) of the space between the active regions 102 needs to be long enough to electrically insulate word lines formed in different active regions 102.

The length (b) of the active region extending in the minor axis direction is formed to be different from the length (d) of the space between the active regions 102. The length (b) is preferably formed to be longer than the length (d).

The length (b) of the active region extending in the minor axis direction is formed to be large enough to enhance the electric field between a drain region connected to a bit line and a body of the semiconductor substrate 100 to increase a tunneling effect.

Referring to FIG. 1b, a plurality of word lines 106 are formed on the semiconductor substrate 100. The word lines 106 extend across the active region 102 and the device isolating film 104. Two word lines 106 are preferably formed in one active region 102.

The word line 106 is formed to extend in a line from a sub word line (not shown) located at one side of a cell array block (not shown) to a sub word line (not shown) located at the other side of the cell array block. In a plurality of word lines, the n^{th} word line 106 and the (n+1)^{th} word line 106 are preferably connected to the different sub word lines.

The length (e1) of the word line 106 extending in the minor axis direction and over the active region 102 can be formed to be identical to or different from the length (e2) of the world line 106 extending in the minor axis direction and over the device isolating film 104.

When the semiconductor device is to be highly integrated, the length (e1) of the word line 106 over the active region 102 is formed to be small, and the length (e2) of the word line over the device isolating film 104 is formed to be large in order to prevent a voltage drop when voltage is applied to the word line 106.

The length (f) of the space between the word lines 106 can be formed to be identical to or different from the lengths (e1, e2) of the word line 106 extending in the minor axis direction.

A gate spacer (not shown) is formed at both sidewalls of the word line 106. Thereafter, an ion-implanting process is performed to form source regions 108a and drain regions 108b in portions of the active region 102 at both sides of the word lines 106.

A source region 108a is formed in a portion of each active region 102 between the two word lines 106 of a single active region 102, and the drain regions 108b are formed in the edge portions of the active region 102.

Referring to FIG. 1c, a plurality of first contact plugs 110 are formed to be connected to the source regions 108a and the drain regions 108b. Each first contact plug 110 is formed to connect to a respective one of the source regions 108a or the drain regions 108b. The widths (g) of the first contact plugs 110 can be formed to be identical to or different from each other.

The first contact plug 110 is preferably formed to have a circular or oval shape. The width (g) of the first contact plug 110 is preferably formed to be smaller than the length (f) of the space between the word lines 106. The first contact plug 110 has a low height, thereby reducing contact resistance.

Referring to FIG. 1d, first metal lines 112a are formed over the first contact plugs 110 connected to the source regions 108a. Simultaneously, second metal lines 112b are formed over the first contact plug 110 connected to the drain regions 108b.

The first metal line 112a is formed in a line extending in the minor axis direction and is connected to the source regions 108a (the source regions are to be used as a common source, as is described below). The first metal lines 112a are formed to overlap the two word lines 106 of an active region by 10˜100 nm.

A ground voltage VSS is applied to the first metal lines 112a so that a current can flow from the source region 108a to the drain region 108b during the transistors operation.

A second metal line 112b is formed to have an overlapping margin with a subsequently formed second contact plug. The second metal line 112b is preferably formed to have a rectangular or square island type shape.

Each second metal lines 112b overlaps the word line 106 over the active region 102 and the device isolating film 104 by 10˜100 nm. The widths of each word line 106 overlapping the respective second metal lines 112b may be identical to or different from each other.

The length (h) of the first metal line 112a extending in the major axis direction can be formed to be identical to or different from the length (i) of the second metal line 112b extending in the major axis direction. In the first metal line 112a, the length (h) extending in the major axis direction of the active region 102 is formed to be identical to or different from the length (h) extending in the major axis direction of the first metal line 112a over the device isolating film 104.

Referring to FIG. 1e, second contact plugs 114 are preferably formed over the second metal lines 112b. The second contact plugs 114 are formed to connect the drain regions 108b to a bit line formed during a subsequent process. The second contact plugs 114 are formed to have a circular or oval shape. The second contact plugs 114 are preferably formed to have the same axis origin as the first contact plugs 110 formed in the drain regions 108b. The second contact plugs 114 are formed on the second metal lines 112b.

Referring to FIG. 1f, a plurality of bit lines 116 are formed over the second contact plugs 114. The bit lines 116 are formed perpendicular to the word lines 106 and the first metal lines 112a. The length (k) of the bit line 116 extending in the minor axis direction is formed to be identical to or smaller than the length of the active region 102 extending in the minor axis direction. The length (l) of the space between the bit lines 116 is formed to be identical to or different from the length (k) of the bit line extending in the minor axis direction.

As can be seen in FIG. 1f, the two word lines 106 formed over the active region share a single source region 108a, and the bit line 116 is positioned to cross the upper portion of the active region 102; and therefore the unit cell size is reduced. In addition, since the connection between the bit line 116 and the drain region 108b is divided into the first contact plug 110 and the second contact plug 114, the contact depth can be lowered resulting in a reduced contact resistance.

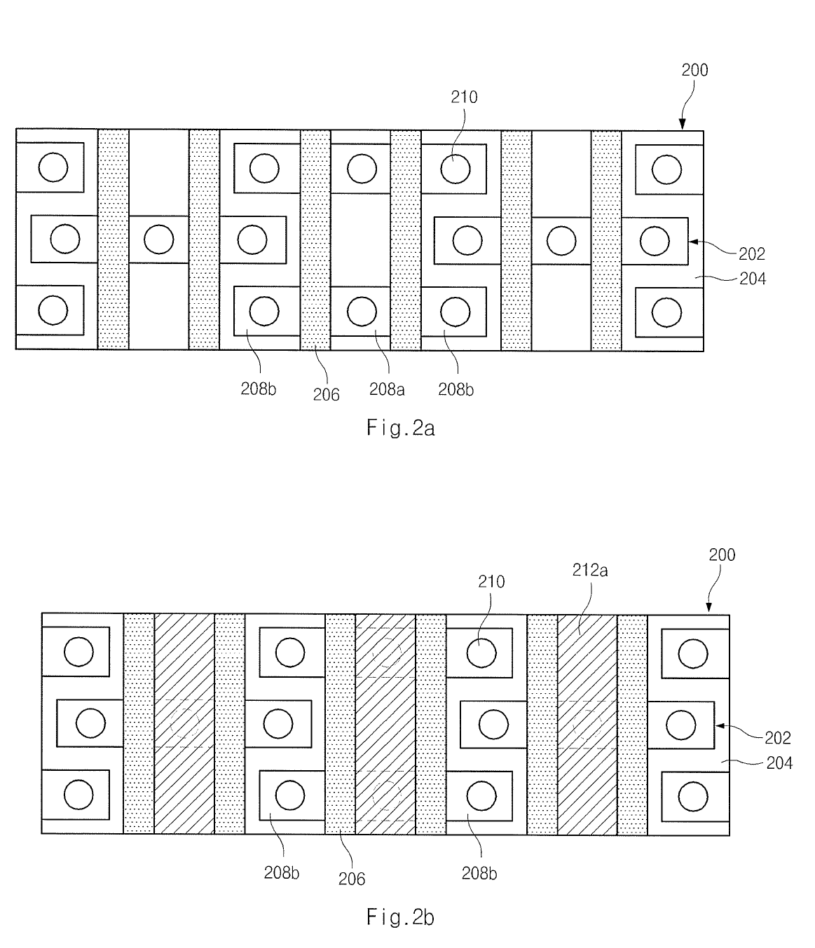

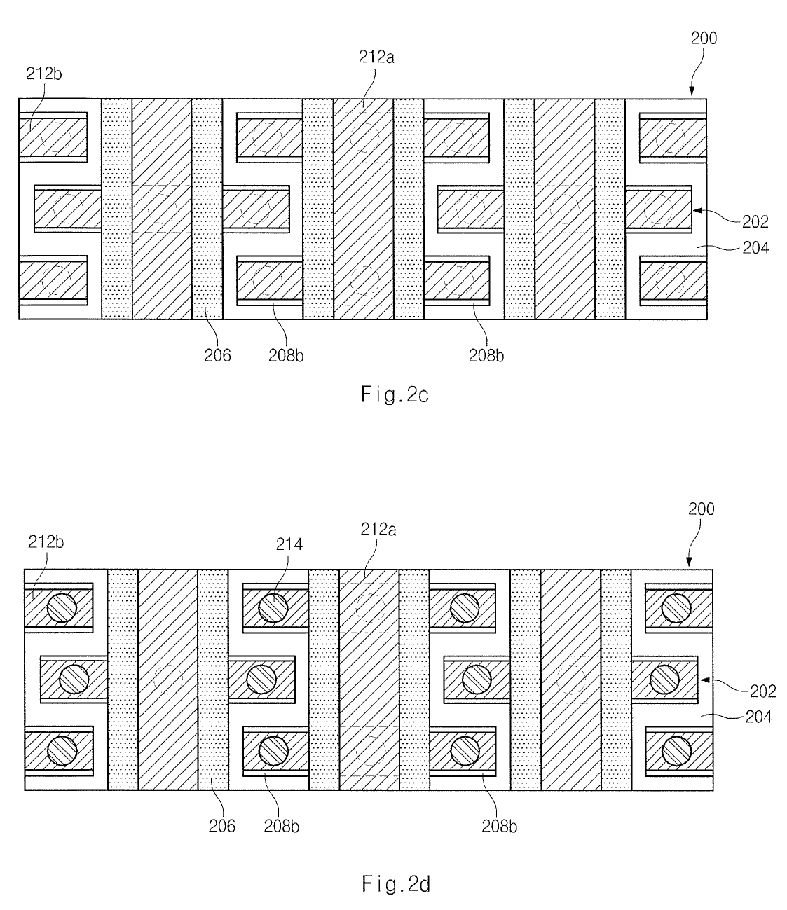

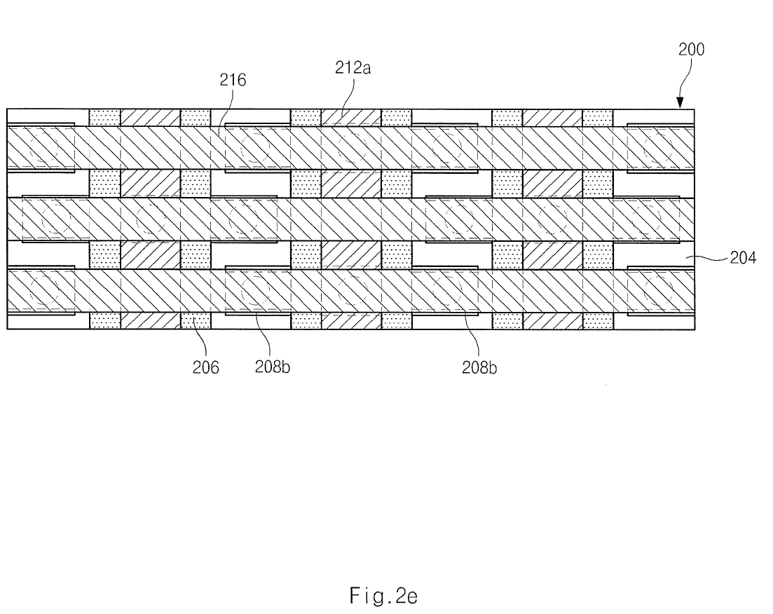

FIGS. 2a to 2e are diagrams showing the layout of a one-transistor type DRAM according to an embodiment of the present invention. The embodiment shown in FIGS. 1a to if is different from that shown in FIGS. 2a to 2e, in that first and second metal lines 212a, 212b are not simultaneously formed. Instead, the first metal line 212a having a shape resembling that of a line is formed, and thereafter the second metal line 212b having an island type shape is formed.

Referring to FIG. 2a, a device isolating film 204 that defines an active region 202 is formed over a semiconductor substrate 200. A plurality of word lines 206 are formed over the semiconductor substrate 200. The word lines 206 are formed to cross the active region 202 and the device isolating film 204. In the one-transistor type DRAM, two word lines 206 are formed in each active region 202.

The word lines 206 are formed to extend in a line from a sub word line (not shown) located at one side of a cell array block (not shown) to a sub word line (not shown) located at the other side of the cell array block.

A gate spacer (not shown) is formed on both sidewalls of the word line 206. An ion-implanting process is performed to form source regions 208a and drain regions 208b in the portions of the active regions 202 at sides of the word line 206.

The source region 208a is formed in the portion of the active region 202 between the two word lines 206, and the drain region 208b is formed in the edge portion of the active region 202.

A plurality of first contact plugs 210 are formed to be connected to each of the source and drain regions 208a and 208b. That is, one of the first contact plugs 210 corresponds to each of the source and drain regions 208a and 208b. The first contact plug 210 is formed to have a circular or oval shape.

Referring to FIG. 2b, first metal lines 212a are formed over the first contact plugs 210 connected to the source region 208a. The first metal lines 212a are connected to respective source regions 208a, (the source regions 208a are used as a common source). The first metal line 212a is formed to extend in a line, and the first metal line 212a overlaps the respective word lines 206 by 10˜100 nm.

A ground voltage VSS is applied to the first metal line 212a so that a current can flow from the source region 208a to the drain region 208b during the transistors operation.

Referring to FIG. 2c, second metal lines 212b are formed over the first contact plugs 210 connected to the drain region 208b. The second metal lines 212b are formed to have a rectangular or square island type shape over the drain regions 208b.

Each second metal line 212b overlaps the word line 206 over the active region 202 and the device isolating film 204 by 10˜100 nm. The widths of each word line 206 overlapping the respective second metal lines 212b may be identical to or different from each other.

As was mentioned above, the first metal line 212a is formed first, and the second metal line 212b is formed thereafter. Forming the first and second metal lines 212a and 212b in this manner prevents over-etching of the edge of the second metal line 212b which can be caused by a shortage of a process margin. Therefore, the second metal line 212b is not formed to be too small.

Referring to FIG. 2d, second contact plugs 214 are formed over the second metal lines 212b. The second contact plugs 214 are preferably formed to connect the drain region 208b to a bit line formed during a subsequent process. The second contact plugs 214 are formed to have a circular or oval shape. The second contact plugs 214 are preferably formed to have the same axis origin as that of the corresponding first contact plugs 210. The second contact plugs 214 are formed on the second metal line 212b.

Referring to FIG. 2e, a plurality of bit lines 216 are formed over the second contact plugs 214. The bit lines 216 are formed perpendicular to the word lines 206 and the first metal lines 212a. The bit lines 216 overlap and are connected to the second contact plugs 214.

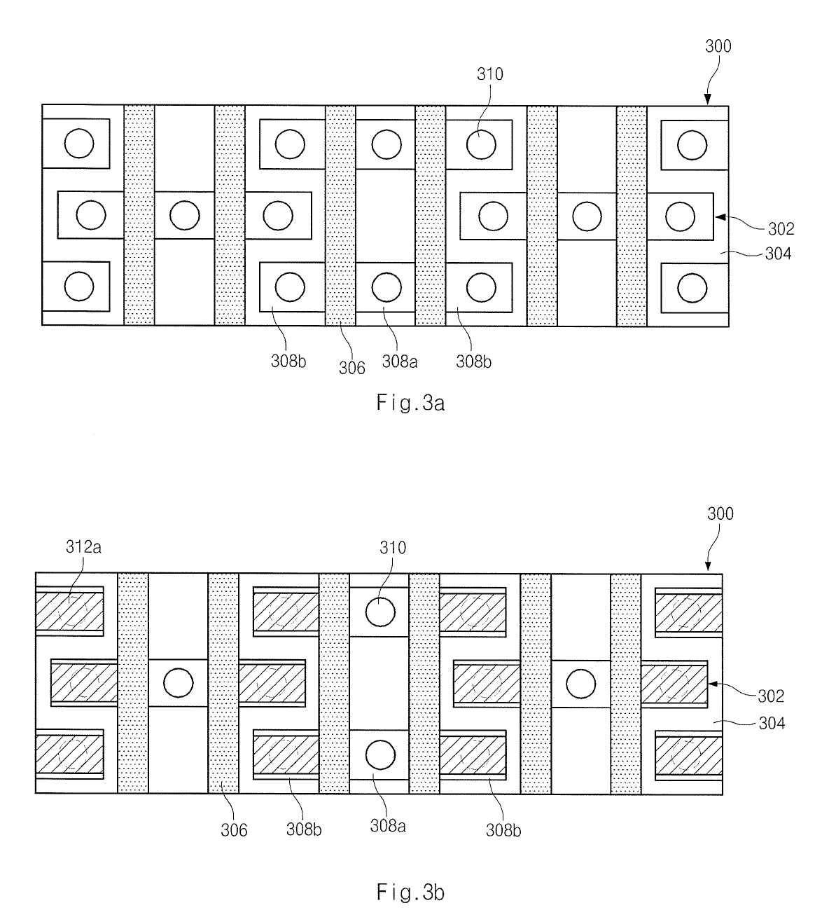

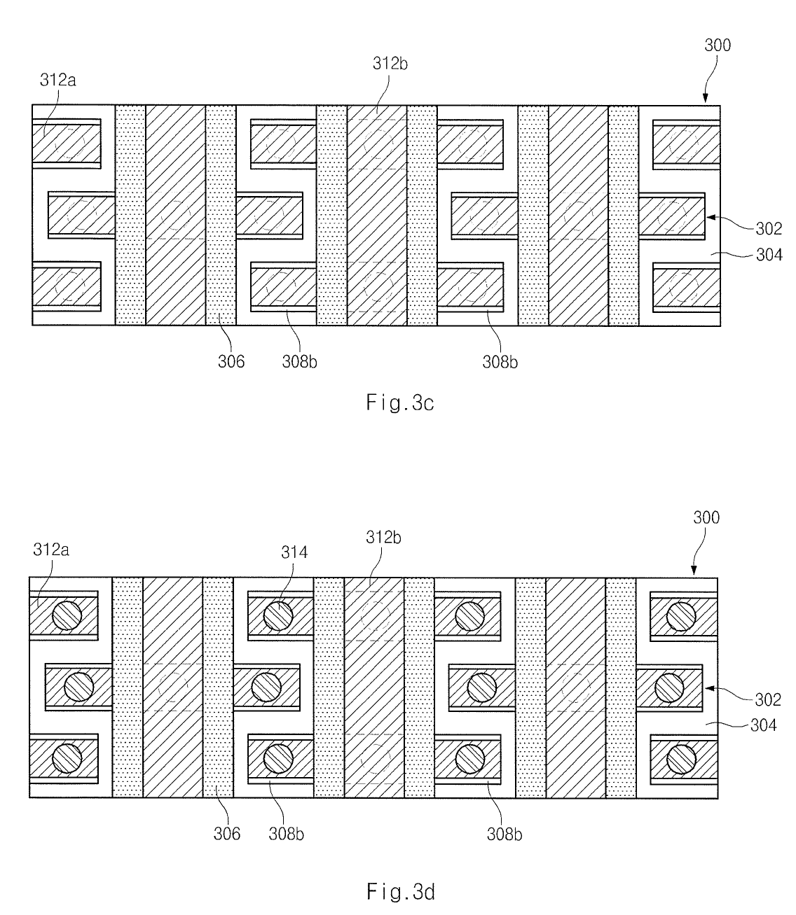

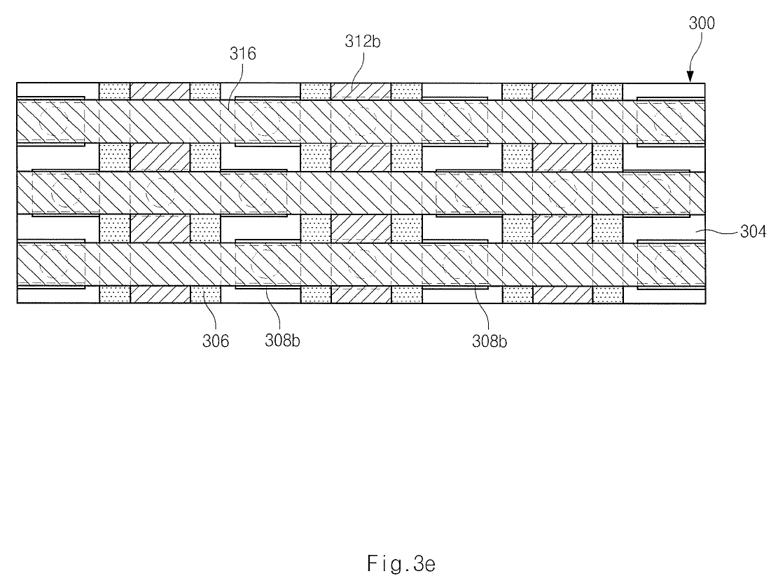

FIGS. 3a to 3e are diagrams showing the layout of a one-transistor type DRAM according to an embodiment of the present invention. The embodiment shown in FIGS. 1a to 1f is different from that shown in FIGS. 3a to 3e, in that first and second metal lines 312a, 312b are not simultaneously formed. Instead, a first metal line 312a having an island type shape is formed, and thereafter a second metal line 312b extending in a line is formed.

Referring to FIG. 3a, a device isolating film 304 that defines an active region 302 is formed over a semiconductor substrate 300. A plurality of word lines 306 is formed over the semiconductor substrate 300. The word lines 306 are formed to cross the active region 302 and the device isolating film 304. Two word lines 306 are formed in each active region 302.

The word line 306 is formed in the shape of a line extending from a sub word line (not shown) located at one side of a cell array block (not shown) to a sub word line (not shown) located at the other side of the cell array block.

A gate spacer (not shown) is formed on both sidewalls of the word line 306. An ion-implanting process is performed to form source regions 308a and drain regions 308b in the active regions 302 at sides of the word lines 306.

A source region 308a is formed in each active region 302 between the two word lines 306 formed in a single active region. The drain regions 308b are formed in the edge portions of the active region 302.

A plurality of first contact plugs 310 are formed such that each first contact plug 310 connects to a respective source or drain region 308a and 308b. That is, each first contact plug 310 corresponds to a source or a drain region 308a, 308b. The first contact plug 310 is formed to have a circular or oval shape.

Referring to FIG. 3b, a first metal line 312a is formed over the first contact plug 310 connected to the drain region 308b. The first metal line 312a is formed over the drain region 308b to have a rectangular or square island type shape.

Each first metal line 312a overlaps the word line 306 over the active region 302 and the device isolating film 304 by 10˜100 nm. The widths of each word line 306 overlapping the respective second metal lines 112b may be identical to or different from each other.

Referring to FIG. 3c, second metal lines 312b are formed over the first contact plugs 310 connected to the source regions 308a. The second metal lines 312b are connected to the source regions 308a (each of which is a a common source). The second metal lines 312b extend in a line parallel to (i.e. they extend in the same direction), and the second metal lines 312b overlap the word lines 306 by 10˜100 nm.

A ground voltage VSS is applied to the second metal line 312b so that a current can flow from the source region 308a to the drain region 308b during the transistors operation.

As mentioned above, the first metal line 312a is formed first, and thereafter the second metal line 312b is formed. This prevents over-etching of the edge of the first metal line 312a which can be caused by a shortage of a process margin. Therefore, the first metal line 312a is not formed to be too small.

Referring to FIG. 3d, a plurality of second contact plugs 314 are formed over the first metal lines 312a. The second contact plugs 314 are formed to connect the drain region 208b to bit lines formed in a subsequent process. The second contact plugs 314 have a circular or oval shape. The second contact plugs 314 are preferably formed to have the same axis origin as that of the first contact plug 110. The second contact plug 314 is formed on the first metal line 312a.

Referring to FIG. 3e, a plurality of bit lines 316 are formed over the second contact plugs 314. The bit lines 316 are formed perpendicular to the word lines 306 and the second metal lines 312b, and the bit lines 316 overlap the second contact plugs 314.

As described above, a one-transistor type DRAM according to an embodiment of the present invention simplifies a manufacturing process without a capacitor process and reduces the height of a chip.

The one-transistor type DRAM includes two transistors that share a single source, and a bit line that crosses the upper portion of an active region to reduce the cell size.

In the one-transistor type DRAM, island-type metal lines are formed over the drain regions, and contact plugs are connected to the island-type metal lines to connect bit lines to the drains, thereby lowering the height of the contact plug and preventing surface damage to the drain.

The above embodiments of the present invention are illustrative and not limitative. Various alternatives and equivalents are possible. For example, the present invention is not limited by the type of deposition, etching, polishing, and patterning steps described herein, nor is the invention limited to any specific type of semiconductor device. For example, the present invention is preferably implemented in a dynamic random access memory (DRAM) device or non-volatile memory device. However, the present invention may be implemented in various other types of semiconductor devices. Those skilled in the art will appreciate that various additions, subtractions, and modifications are possible without departing from the scope of the invention as disclosed in the accompanying claims.

What is claimed is:

1. A one-transistor type DRAM having an active region defined by a device isolating film formed on a semiconductor substrate, the one-transistor type DRAM comprising:
a first word line and a second word line extending across the active region;
a common source region formed in the active region between the first word line and the second word line;
drain regions formed in the portions of the active region outside of the first and second word lines;
a first metal line connected to the common source region;
second metal lines connected to the drain regions; and
a bit line formed over the active region and connected to the second metal lines.

2. The one-transistor type DRAM according to claim 1, wherein each of the first metal line and the second metal lines is connected to the common source region and the drain regions through a first contact plug.

3. The one-transistor type DRAM according to claim 2, wherein the first contact plug has a circular or oval shape.

4. The one-transistor type DRAM according to claim 1, wherein the first and second word lines extend through the active region and the device isolation film, and the first metal line extends linearly in a direction parallel to the first and second word lines.

5. The one-transistor type DRAM according to claim 4, wherein the first metal line overlaps the first and second word lines by 10˜100 nm.

6. The one-transistor type DRAM according to claim 1, wherein each of the second metal lines is formed to have an island type shape over the drain region.

7. The one-transistor type DRAM according to claim 6, wherein the island type shape is rectangular or square.

8. The one-transistor type DRAM according to claim 6, wherein the second metal lines overlap the first and second word lines by 10˜100 nm.

9. The one-transistor type DRAM according to claim 1, wherein the bit line is connected to the second metal lines through second contact plugs.

10. The one-transistor type DRAM according to claim 9, wherein the second contact plug has a circular or oval shape.

11. The one-transistor type DRAM according to claim 10, wherein corresponding first and second contact plugs connecting the drain regions to the bit line share a common axis origin.

12. The one-transistor type DRAM according to claim 1, wherein 10 the bit line overlaps the active region and is perpendicular to the first and second word lines.

13. A method for manufacturing a one-transistor type DRAM, the method comprising:
forming a device isolating film on a semiconductor substrate to define an active region;
forming a first word line and a second word line that extend across the active region and over the device isolating film;
forming a common source region in the active region between the first word line and the second word line;
forming a drain region in the active region outside of the first and second word lines;
forming a first metal line connected to the common source region and a second metal line connected to the drain region, wherein the first and second metal lines are formed simultaneously; and
forming a bit line connected to the second metal line.

14. The method according to claim 13, wherein the first and second word lines are formed to be parallel to each other, and the first metal line is formed to extend in a line that is parallel to the first and second word lines.

15. The method according to claim 13, wherein the bit line is formed to be perpendicular to first and second word lines and to overlap the active region.

16. A method for manufacturing a one-transistor type DRAM, the method comprising:
forming a device isolating film on a semiconductor substrate to define an active region;
forming a first word line and a second word line that extend across the active region and over the device isolating film;
forming a common source region in the active region between the first word line and the second word line;
forming a drain region in the active region outside of the first and second word lines;
forming a first metal line connected to the common source region to have a line type;
forming a second metal line connected to the drain region, wherein the second metal line is formed as an island over the drain region and the second metal line is formed after the first metal line; and
forming a bit line connected to the second metal line.

17. The method according to claim 16, wherein the first and second word lines are formed to be parallel to each other, and the first metal line is formed parallel to the first and second word lines.

18. The method according to claim 16, wherein the bit line is formed to be perpendicular to the first and second word lines and to overlap the active region.

19. A method for manufacturing a one-transistor type DRAM, the method comprising:
forming a device isolating film on a semiconductor substrate to define an active region;
forming a first word line and a second word line that extend across the active region and over the device isolating film;
forming a common source region in the active region between the first word line and the second word line;
forming a drain region in the active region outside the first and second word lines;
forming a first metal line connected to the drain region, wherein the first metal line is formed as an island over the drain region;
forming a second metal line connected to the common source region to have a line type, wherein the second metal line is formed after the first metal line; and
forming a bit line connected to the second metal line.

20. The method according to claim 19, wherein:
the first and second word lines are formed to be parallel to each other, and the first metal line is formed parallel to the first and second word lines, and
the bit line is formed to be perpendicular to the first and second word lines and to overlap the active region.
